(19) United States
(12) Patent Application Publication
(10) Pub. No.: US 2014/0262040 A1
(43) Pub. Date: Sep. 18, 2014

(54) METHOD AND SYSTEM USING PLASMA TUNING RODS FOR PLASMA PROCESSING

(71) Applicant: TOKYO ELECTRON LIMITED, Tokyo (JP)

(72) Inventors: Jianping Zhao, Austin, TX (US); Peter L. G. Ventzek, Austin, TX (US); Lee Chen, Cedar Creek, TX (US); Barton Lane, Austin, TX (US); Merritt Funk, Austin, TX (US); Radha Sundararajan, Dripping Springs, TX (US); Iwao Toshihiko, Tokyo (JP); Zhiying Chen, Austin, TX (US)

(21) Appl. No.: 13/842,965

(22) Filed: Mar. 15, 2013

(51) Int. Cl. H01J 37/32

(52) U.S. Cl. CPC H01J 37/32211
USPC 156/345.41; 118/723 MW; 315/32

(57) ABSTRACT

A plasma-tuning rod configured for use with a microwave processing system. The waveguide includes a first dielectric portion having a first outer diameter. A second dielectric portion, with a second outer diameter greater than the first outer diameter surrounds the first dielectric portion, and may be coaxial therewith. In some embodiments of the present invention, a dielectric constant of the first dielectric portion may be equal to or greater than a dielectric constant of the second dielectric portion.

This application is related to co-pending U.S. application Ser. No. 13/249,418, filed on Sep. 30, 2011, and entitled PLASMA-TUNING RODS IN SURFACE WAVE ANTENNA (SWA) SOURCES; U.S. application Ser. No. 13/249,485, filed on Sep. 30, 2011, and entitled PLASMA TUNING RODS IN MICROWAVE PROCESSING SYSTEMS; and U.S. application Ser. No. 13/249,560, filed on Sep. 30, 2011, and entitled PLASMA TUNING RODS IN MICROWAVE RESONATOR PLASMA SOURCES.

### FIELD OF THE INVENTION

The present invention relates to substrate processing and, more particularly, to microwave processing systems for substrate processing.

### BACKGROUND OF THE INVENTION

Typically, during semiconductor processing, a (dry) plasma etch process is utilized to remove or etch material along fine lines or within vias or contracts patterned on a semiconductor substrate. The plasma etch process generally involves positioning a semiconductor substrate with an overlying patterned, protective layer, for example, a photoresist layer, into a process chamber.

Once the substrate is positioned within the process chamber, an ionizable, dissociative gas mixture is introduced into the process chamber at a pre-specified flow rate, while a vacuum pump is throttled to achieve an ambient process pressure. Thereafter, a plasma is ignited by ionizing a portion of the gas species in the process chamber, such as argon, to yield argon gas ions and energetic electrons. The electrons may also serve to dissociate some species of the gas mixture and create one or more reactant species suitable for etching the exposed surfaces. Once the plasma is formed, any exposed surface of the substrate is etched. The process is adjusted to achieve optimal conditions, including an appropriate concentration of desirable reactant and ion populations to etch various features (e.g., trenches, vias, contacts, etc.) in the exposed regions of the substrate. Such substrate materials where etching is required include silicon dioxide (SiO₂), poly-silicon, and silicon nitride, for example.

Plasma processing is also used for deposition, stripping, ashing, etc., and thus, is not limited to etch processes. For example, plasma CVD is used to process flat panel and solar displays and for OLED.

Various techniques have been implemented for exciting a gas into plasma for the treatment of a substrate during semiconductor device fabrication, as described above. In particular, capacitively coupled plasma (“CCP”) or inductively coupled plasma (“ICP”) processing systems have been utilized commonly for plasma excitation. Among other types of plasma sources, there are microwave plasma sources (including those utilizing electron-cyclotron resonance (“ECR”)), surface wave plasma (“SWP”) sources, and helicon plasma sources.

Microwave processing systems offer improved plasma processing performance, particularly for etching processes, over CCP systems, ICP systems, and resonantly heated systems. Microwave processing systems produce a high degree of ionization at a relatively lower Boltzmann electron temperature (Tₑ). In addition, these systems generally produce a plasma that is rich in electronically excited molecular species with reduced molecular dissociation. However, the practical implementation of microwave processing systems still suffers from several deficiencies including, for example, plasma uniformity and stability.

In addition, conventional microwave plasma systems have used tuning rods constructed from a metal core and a quartz or dielectric shell for delivering microwave power into the process chamber. However, the materials comprising these tuning rods have such varying thermal expansion coefficients that inherent heat loading issues result, including, for example, low thermal strength. Additionally, at high temperatures, the metal core may melt, evaporate, and deposit onto the inner surface of the outer, dielectric shell, which affects the tuning rod's ability to couple microwave energy into the plasma. The electromagnetic mode is usually TEM (transverse electromagnetic) in the case of a metal core.

There exists a need for improved tuning rod structures that overcome the above noted deficiencies, such as heat loading and power coupling uniformity along the rods, while improving energy deposition and plasma formation, uniformity and stability.

### SUMMARY OF THE INVENTION

The present invention overcomes the foregoing problems and other shortcomings and drawbacks of known microwave processing systems that couple microwave power to a plasma using a dielectric tuning rod. While the present invention will be described in connection with certain embodiments, it will be understood that the present invention is not limited to these embodiments. To the contrary, this invention includes all alternatives, modifications, and equivalents as may be included within the scope of the present invention.

In accordance with one embodiment of the present invention, a plasma-tuning rod configured for use with a microwave processing system includes a first dielectric portion having a first outer diameter. A second dielectric portion, with a second outer diameter greater than the first outer diameter, surrounds the first dielectric portion. In some aspects of the present invention, a dielectric constant of the first dielectric portion may be different than a dielectric constant of the second dielectric portion.

In accordance with another embodiment of the present invention, a plasma-tuning rod includes a first dielectric portion and a second dielectric portion that is coaxial with respect to the first dielectric portion. Both dielectric portions comprise one or more layers of materials. At least one of the one or more layers of the first dielectric portion has a dielectric constant that is different than a dielectric constant of at least one of the one or more layers comprising the second dielectric portion.

Still another embodiment of the present invention includes a microwave processing system having a process chamber configured to contain a plasma. A substrate support within the process chamber is configured to support a substrate thereon. The process chamber receives at least one process gas from a process gas supply system and a microwave generator generates electromagnetic energy. A plurality of plasma-tuning rods is operably coupled to the process chamber and configured to receive the electromagnetic energy from the microwave generator and to transfer the electromagnetic energy into the process chamber for igniting the plasma. Each of the plurality of plasma-tuning rods includes a core and a shell. The core includes a first dielectric material, and the shell includes a second dielectric material surrounding the core.

According to some aspects of the embodiment of the present invention, the first and second materials comprising the core and the shell, respectively, may have different dielectric constants.

### BRIEF DESCRIPTION OF THE FIGURES

The accompanying drawings, which are incorporated in and constitute a part of this specification, illustrate embodiments of the present invention and, together with a general description of the invention given above, and the detailed description of the embodiments given below, serve to explain the principles of the present invention

FIG. 1 illustrates a microwave processing system in accordance with one embodiment of the present invention, across a length-wise cross-section of the microwave processing system.

FIG. 2 illustrates a top view of the microwave processing system of FIG. 1.

FIG. 2A illustrates a portion of the microwave processing system encircled 2A in FIG. 2.

FIGS. 3A-3B, 4A-4B, 5A-5B and 6A-6B each illustrate a plasma tuning portion of a waveguide, in cross-section, for use with the microwave processing system of FIG. 1 and in accordance with various embodiments of the present invention.

FIGS. 7A-7C illustrate in cross-sectional view embodiments of a plasma-tuning rod with a hemispheroidal-shaped tip.

FIGS. 8A-8B illustrate in cross-sectional view embodiments of a plasma-tuning rod with a rounded cone-shaped tip.

FIGS. 9A-9C illustrate in cross-sectional view embodiments of a plasma-tuning rod with a slab-shaped tip.

### DETAILED DESCRIPTION

A microwave processing system is disclosed in various embodiments. However, one skilled in the relevant art will recognize that the various embodiments may be practiced without one or more of the specific details, or with other replacement and/or additional methods, materials, and components. In other instances, well-known structures, materials, or operations are not shown or described in detail to avoid obscuring aspects of various embodiments of the present invention.

Similarly, for purposes of explanation, specific numbers, materials, and configurations are set forth in order to provide a thorough understanding of the present invention. Nevertheless, the present invention may be practiced without specific details. Furthermore, it is understood that the various embodiments shown in the figures are illustrative representations and not necessarily drawn to scale.

Referring now to the drawings, and in particular to FIGS. 1 and 2, a microwave processing system 20 according to one embodiment of the present invention is shown. The microwave processing system 20 includes a process chamber 22 having at least one side wall 24 and configured to form a plasma 26 therein. The process chamber may be cylindrical, for example, having one side wall 24, or may be square or rectangular, for example, having four side walls 24, as depicted in FIG. 2. By way of example, and not limitation, the process chamber 22 may be several meters in length, width or diameter, or any other size needed to effectively process a particular type of substrate, such as 200 mm, 300 mm, 400 mm, etc. semiconductor wafers, OLEDs, flat panel displays, and solar panels. A substrate holder 28 for supporting a substrate 30 or a plurality of substrates 30 thereon is positioned within the process chamber 22. Substrate holder 28 may be stationary, or may be movable, either rotatably or vertically.

In the embodiment shown, having a rectangular process chamber 22, two electromagnetic energy tuning systems 32, 34 are positioned near a top portion of the process chamber 22, at a height above the substrate 30 and substrate holder 28, and positioned adjacent opposing walls 24 alongside the process chamber 22. Each tuning system 32, 34 includes at least one cavity wall 36, 38 surrounding a respective cavity 40, 42. In one example, the tuning systems 32, 34 extend approximately the length of the process chamber 22, and may be longitudinally offset with respect to the one another. In other embodiments, a single tuning system (e.g., 32) may be provided, such as a ring-shaped tuning system that wraps around a cylindrical chamber or a single tuning system on only one side of a square or rectangular chamber. In yet other embodiments, more than two tuning systems may be provided, such as a plurality of radially spaced tuning systems around a cylindrical chamber, or four tuning systems, one on each side wall of a square or rectangular chamber.

Further to the embodiment shown in FIG. 1, An electromagnetic source 44, 46 (illustrated as “EM source”) may be coupled to each tuning system 32, 34 via a matching network 48, 50 and a coupling network 52, 54. The coupling network 52, 54 may be used to provide microwave energy to the respective tuning system 32, 34 as is described in greater detail below.

A controller 56 is operably coupled to the electromagnetic sources 44, 46, the matching networks 48, 50, and the coupling networks 52, 54 and is configured to operate each in accordance with a particular process recipe. The electromagnetic sources 44, 46 may be configured to operate at a frequency ranging from about 500 MHz to about 5000 MHz.

The controller 56 may further be operably coupled to a gas supply system 58 and showerhead 60, which are configured to inject one or more processing gases in the process chamber 22. During dry plasma etching, the processing gases may comprise one or more of an etchant, a passivant, and an inert gas. For example, when plasma etching a dielectric film, such as silicon oxide (“SiOₓ”) or silicon nitride (“SiₓN_{y}”), one suitable plasma etch gas composition may include a fluorocarbon-based chemistry (“CₓF_{y}”), including, for example, C₄F₈, C₅F₈, C₄F₆, CF₄ and/or a fluorohydrocarbon-based chemistry (“CₓH_{y}F_{z}”), including, for example, CHF₃, CH₂F₂. The inert gas may be, for example, O₂, CO, or CO₂. When etching polycrystalline silicon (polysilicon), the plasma etch gas composition may include a halogen-containing gas, such as HBr, Cl₂, NF₃, or SF₆ and/or a fluorohydrocarbon-based chemistry (“CₓH_{y}F_{z}”), including, for example, CHF₃ and CH₂F₂. During plasma-enhanced deposition, the process gas may comprise a film forming precursor, a reduction gas, and an inert gas, or a combination thereof.

The controller 56 may additionally be operably coupled to a pressure control system 62, e.g., a pump, in fluid communication with the process chamber 22. The pressure control system 62 is configured to evacuate the process chamber 22 and to control the pressure within the process chamber 22.

The controller 56 may also be operably coupled to one or more one or more plasma sensors 63 and/or process sensors 65, which are arranged about the microwave processing system 20 and coupled to the wall 24 thereof. These sensors 63, 65 obtain data relative to the plasma ignited within the process chamber 22 and a process status with respect to processing of the substrate 30.

Each tuning system 32, 34 includes one or a plurality of plasma-tuning rods 64, 66, respectively, with five plasma-tuning rods 64, 66 being depicted as an example in FIG. 2 in each tuning system 32, 34. It may be readily appreciated that the illustrated number of plasma-tuning rods 64, 66 in each plurality need not be so limited. Each plasma-tuning rod 64, 66 includes a rod-like structure having a plasma tuning portion 68 and 70 and a corresponding electromagnetic tuning portion 72 and 74 and is coupled to the tuning systems 32, 34 via isolation assemblies 76 and 78, which coupling may be movable or stationary.

As specifically shown in FIG. 2, plasma-tuning rods 64, 66 may be arranged in a linear, alternating, equidistant manner so as to extend the length of the process chamber 22, or may be arranged radially in a cylindrical chamber. By way of example only, and not limitation, the distance between adjacent ones of the plurality of plasma-tuning rods 64, 66 may range from about 5 mm to about 50 mm or longer, or within the same tuning system 32, 34, from about 10 mm to about 100 mm or longer. The pluralities of plasma-tuning rods 64, 66 may be positioned at a height ranging from about 100 mm to about 400 mm or more relative to the base of the process chamber 22. In alternative embodiments, the plasma-tuning rods 64, 66 may be arranged in non-linear fashion, at varying heights in the chamber, and in any alternating or non-alternating fashion, to form any desired pattern.

Each of the plasma tuning portions 68, 70 extends into the process chamber 22 by a distance that ranges, for example, from about 10 mm to about 400 mm, or even up to several meters. For example, the plasma tuning portions 68, 70 can extend into the process chamber 22 all the way to the opposite wall. The corresponding electromagnetic tuning portion 72, 74 extends into the respective tuning cavity 40, 42 for example, by a distance up to about 100 mm or greater and may be wavelength dependent, varying from λ/4 to about 10λ of the electromagnetic energy generated by the electromagnetic sources 44, 46.

With specific reference now to FIGS. 2 and 2A, details of the electromagnetic tuning portions 72, 74 within the tuning cavities 40, 42 are described in greater detail. While only one electromagnetic tuning portion 72, 74 is shown and described in FIG. 2A, it would readily appreciated by those of ordinary skill in the art that all electromagnetic tuning portions 72, 74 as well as the plasma tuning portions 68, 70 comprising the pluralities of plasma-tuning rods 64, 66 may be constructed similarly, although this is not required and construction may vary in accordance with embodiments of the present invention.

Electromagnetic coupling regions 80 and 82 are located at a distance, d, from the inner walls 41, 43 of the respective cavities 40, 42, for example, ranging from 0.1 mm to about 100 mm or greater, which may be wavelength dependent, varying from λ/4 to about 10λ. The electromagnetic coupling regions 80, 82 are configured to receive electromagnetic energy from the respectively coupled electromagnet assemblies (each includes the electromagnetic source 44, 46 and the matching and coupling networks 48, 50, 52, 54). The electromagnetic tuning portions 72, 74 extend into the respective electromagnetic coupling regions 80, 82 and are configured to transfer the electromagnetic energy from the electromagnetic coupling regions 80, 82, along the respective plasma tuning portions 68, 70, to a location within the process chamber 22, proximate the plasma tuning portions 68, 70. Each electromagnetic coupling region 80, 82 may comprise at least one of a maximum electromagnetic field region, voltage region, energy region, or current region.

Directly opposing or otherwise adjacent to the electromagnetic tuning portions 72, 74 and electromagnetic coupling regions 80, 82 are tuning slabs 84 and 86 with corresponding control assemblies 88 and 90. The control assemblies 88, 90 are configured to move the respective tuning slabs 84, 86 within the respective tuning cavities 40, 42 and relative to a tunable distance, l, from the respective electromagnetic tuning portions 72, 74. By way of example, and not limitation, tunable distances may vary from about 0.01 mm to about 100 mm or greater and may be wavelength dependent, varying from about λ/4 to about 10λ. The tunable distances, l, may be individually and separately optimized so as to adjust, control, and maintain plasma uniformity with the process chamber 22 (FIG. 1).

Referring again to FIG. 2, the tuning cavities 40, 42 may also include at least one cavity tuner 91, 93, each comprising a tuning slab 92, 94 and a control assembly 96, 98. The cavity tuners 91, 93 are illustrated to be positioned on a lateral side of the respective tuning cavity 40, 42 and, indeed, are offset from the cavity center; however, other positions may also be used. The cavity tuners 91, 93 may be individually and separately optimized so as to further adjust, control, and maintain plasma uniformity with the process chamber 22 (FIG. 1).

Turning now to FIG. 3A, a cross-section of the plasma tuning portion 68 of the plasma-tuning rod 64 is shown in accordance with one exemplary embodiment of the present invention. While the cross-section in this and subsequent figures is of the plasma tuning portion 68 the constructions described apply also to the plasma tuning portions 70 and electromagnetic tuning portions 72, 74, and thus to the plasma-tuning rods 64, 66 as a whole. The plasma tuning portion 68, as shown, includes a coaxial construction comprising an inner dielectric portion 102 (also referred to as a core) of a first radius (r₀) associated with its outer diameter and an outer dielectric portion 104 (also referred to as a shell) of a second radius (r₁) associated with its outer diameter. In this particular embodiment, the materials comprising the dielectric portions 102, 104 vary in dielectric constants, ∈₁ and ∈₂, respectively (or permittivity). For example, the inner dielectric portion 102 may be constructed from aluminum oxide (Al₂O₃) having a dielectric constant (∈₁) of about 9; the outer dielectric portion 104 may be constructed from silicon dioxide (SiO₂) having a dielectric constant (∈₂) of about 3.5. However, the dielectric constants may the same. In accordance with an embodiment of the invention, the dielectric constant of the inner dielectric portion 102 may be equal to or greater than the dielectric constant of the outer dielectric portion 104. The material and radius of each dielectric portion 102, 104 may be selected, and optimized, with respect to one another, to achieve uniform and efficient power delivery to the process chamber 22 (FIG. 1) along the dielectric plasma-tuning rod 64.

In an alternative embodiment, the inner dielectric portion 102 is not coaxial with the outer dielectric portion 104, but is axially offset. Thus, embodiments of the invention shown and described as coaxial need not be so limited. However, coaxial alignment may have benefits, in manufacture and effect, as may be appreciated by persons skilled in the art.

In another, similar embodiment shown in FIG. 3B, the cross-section of another plasma tuning portion 68′ is shown and includes a first dielectric portion 108 of a first radius (r₀) and first dielectric constant (∈₁) similar to the first dielectric portion 102 of FIG. 3A and a first intermediate portion 110 having a second radius (r₁) that is smaller than the second dielectric portion 104 of FIG. 3A while having a second dielectric constant (∈₂) that is similar to the second dielectric portion 104 of FIG. 3A. The plasma tuning portion 68 further includes a second intermediate portion 112 of a third radius (r₂) and having the same ∈₁ value as the first dielectric portion 108, and an outer dielectric portion 114 of a fourth radius (r₃) and having the same ∈₁ value as the first intermediate portion 110. Like the plasma tuning portion 68 of FIG. 3A, and by way of example, the materials comprising this plasma tuning portion 68′ may include Al₂O₃ and SiO₂.

FIGS. 4A and 4B illustrate plasma tuning portions 116, 116′ in accordance with alternative embodiments of the present invention. The plasma tuning portions 116, 116′ each include a dielectric core 120, 120′ having a first radius (r₀) and a dielectric shell 124, 124′ having a second radius (r₁), separated by an gas band 128 having a third radius (r₂) therebetween. As defined, the dielectric constant of a vacuum, and thus the gas band 128, (∈ₐᵢᵣ) is 1. In one embodiment, the gas is air. In another embodiment, the gas is N₂ or an inert gas.

The materials comprising the core 120 and the shell 124 are dielectric in nature and vary with respect to one another as was described previously. Alternatively, the core 120′ and the shell 124′ of plasma tuning portion 116′ of FIG. 4B are constructed from the same dielectric material. In yet another alternative embodiment, depicted in FIG. 4B, the shell 124′ includes a metal slot antenna on the inner surface thereof adjacent the gas band 128.

FIGS. 5A and 5B illustrate plasma tuning portions in accordance with still other embodiments of the present invention. For example, in FIG. 5A, the plasma tuning portion 132 includes a dielectric shell 134 comprising a plurality of layers 137 (of which three are shown) spaced away from the dielectric core 136 by an gas band 139. At least one layer 138 of the plurality 137 in the dielectric shell 134 has a dielectric constant (∈₁) similar to that of the dielectric core 136. In fact, the at least one layer 138 in the dielectric shell 134 may be the same material as the dielectric core 136. Also, as shown, at least one layer 140 of the plurality 137 has a dielectric constant (∈₂) differing from ∈₁ of the at least one layer 138. Moreover, the dielectric core 136 and the plurality of layers 137 may be constructed, in still other embodiments, from dielectric materials, all of which have a different dielectric constant value.

Because the thickness of the shell 134 affects an evanescent field strength, e.g., the evanescent field transmitted from the plasma tuning portion 132 for coupling into the plasma 26 (FIG. 1), the thickness, and number, of layers 137 comprising the shell 134 may be selected so as to achieve the desired degree of coupling. Additionally, an outermost layer of the shell 134 may be selected for compatibility with the process gases to be used in a particular processing method. For example, a predominantly fluorocarbon etch chemistry may erode certain oxide dielectric materials, such that the incompatible materials could be restricted to inner layers of the shell 134.

In addition to the plurality of layers 137 of the shell 134, the dielectric core 136′ may also include a plurality of layers 146, as shown in the plasma tuning portion 132′ of FIG. 5B. At least one layer 142 of the plurality 146 in the dielectric core 136′ has a first dielectric constant (∈₁) different than a second dielectric constant (∈₂) of at least one layer 140′ of the shell 134′. Other layers 143 of the plurality 146 may be the same material as one or more of the plurality of layers 137′ of the shell 134′. Alternatively, the layers 138′, 143 may be different materials than either or both of the layers 140′, 142. Again, the numbers and thicknesses of the layers of the plurality 146 may vary and are selected to produce the desired degree of energy coupling.

In still other embodiments, such as the plasma tuning portions 150, 150′ of FIGS. 6A and 6B, the dielectric core 152 may include a central strut 154 having a diameter much smaller than rₒ of the dielectric core 152. The dielectric constant of the central strut 154 may be unequal to the dielectric constant of the core remainder 156. Although not shown, the shell may include a single layer spaced from the core 152 by an gas band 160, which may be of a similar dielectric material to the material comprising the strut 154, and as shown and described in detail above for single layer shell 124 of FIG. 4A. Alternatively, the central strut 154 may be a metal strut. As shown in FIGS. 6A and 6B, the dielectric shells 158, 158′ may include a plurality of layers 162, 162′, 164, 164′, 166, wherein each layer of the plurality 162, 162′, 164, 164′, 166 includes a dielectric material. Alternatively, the layers 162, 162′, 164, 164′, 166 may be constructed such that at least one layer has a second dielectric constant (∈₂) different than the first dielectric constant (∈₁) of the core remainder 156. The layers shown herein, two layers in FIG. 6A and three layers in FIG. 6B, are not necessarily limiting.

Thus, in accordance with present invention, a microwave processing system includes a plurality of plasma-tuning rods configured to transfer microwave energy from a microwave energy source to the process chamber. Each plasma-tuning rod includes a plasma tuning portion and an electromagnetic tuning portion being constructed from a dielectric shell surrounding a dielectric core, and that may be coaxial with respect to the dielectric core, with or without an intervening gas band therebetween. Either or both of the dielectric core and/or the dielectric shell may comprise more than one layer. The dielectric core and the dielectric shell may have a similar dielectric constant or, in some instances, the dielectric core (or at least one layer thereof) has a different dielectric constant than the dielectric shell (or at least one layer thereof).

Referring again to FIG. 1, and in use of the illustrated microwave processing system 20, electromagnetic energy from the electromagnetic sources 44, 46, matching networks 48, 50, and coupling networks 52, 54 is coupled to the tuned electromagnetic coupling regions 80, 82 within the cavities 40, 42. From there, electromagnetic energy may be transferred to the electromagnetic tuning portions 72, 74, the plasma tuning portions 68, 70, and ultimately to the process chamber 22 to ignite and/or sustain the plasma 26. The plasma-tuning rods 64, 66 comprising the electromagnetic tuning portions 72, 74 and the plasma tuning portions 68, 70 uniformly deliver the electromagnetic energy into the plasma 26 without the issues noted above by the known, conventional tuning rods. The tuning slabs 84, 86 may be moved with respect to the electromagnetic coupling regions 80, 82 to manipulate and control plasma uniformity.

Referring further to FIGS. 1 and 2, the plasma tuning portions 68, 70 are shown to extend a significant distance into the process chamber 22. However, this is not required. In fact, a relatively short extension into the process chamber may have benefits in certain embodiments, for example, may provide a smoother rod-plasma interface and a shorter plasma/microwave propagation length along the rod, which may benefit molecular gases. Several exemplary embodiments for plasma tuning portion configurations are depicted in FIGS. 7A-9C in which the plasma tuning portion extends only a short distance into the process chamber.

In FIGS. 7A-7B, a plasma-tuning rod 200a is coupled to an isolation assembly 76 (as previously described in FIGS. 1-2A) and includes a cylindrical section 202 and a non-cylindrical tip 204a, which has a hemispheroidal shape. In FIG. 7A, only the non-cylindrical tip 204a extends into the process chamber (not shown) as a plasma tuning portion 206. In FIG. 7B, both the non-cylindrical tip 204a and a portion of the cylindrical section 202 extend into the process chamber as a plasma tuning portion 206. FIG. 7C is similar to FIG. 7A, but the diameter D_{H} of the non-cylindrical tip 204a inside the process chamber adjacent the isolation assembly 76 is greater than the diameter D_{I} of the aperture 276 in the isolation assembly 76 (and greater than a diameter of cylindrical section 202). Thus, the metal around the edge of the isolation assembly is covered by the dielectric material of the plasma-tuning rod 200a as it enters the process chamber.

FIGS. 8A-8B are similar to FIGS. 7A-7B. A plasma-tuning rod 200b is coupled to isolation assembly 76 and includes a cylindrical section 202 and a non-cylindrical tip 204b, which in this embodiment, has a rounded cone shape. In FIG. 8A, only the non-cylindrical tip 204b extends into the process chamber as a plasma tuning portion 206. In FIG. 8B, both the non-cylindrical tip 204b and a portion of the cylindrical section 202 extend into the process chamber as a plasma tuning portion 206.

FIGS. 9A-9C depict an alternative embodiment similar to FIG. 7C in which the metal around the edge of the isolation assembly 76 is covered by the dielectric material of a plasma-tuning rod 200c as it enters the process chamber (not shown). Plasma-tuning rod 200c is coupled to isolation assembly 76 and includes a cylindrical section 202 and a slab tip 208, having a rounded edge 208a, where a transverse axis A_{T} of the slab tip is transverse to a longitudinal axis A_{L} of the cylindrical section 202. Only the slab tip 208 extends into the process chamber as a plasma tuning portion 206. As shown in FIG. 9A, a curved radius 210 may be provided where the longitudinally-extending cylindrical section 202 transitions to the transversely-extending slab tip 208, which radius 210 may mate with a curved edge radius at the edge 278 of the aperture 276. As also shown in FIG. 9A, the rounded edge 208 may be positioned immediately adjacent to the curved radius 210, or as shown in FIG. 9B, the rounded edge 208 may be offset from the curved radius 210 by a transition section 208b lying substantially flush with an inner planar surface 280 of the isolation assembly 76. In FIG. 9C, the aperture 276 has a straight edge 278′, and a straight corner junction 210′ may be provided where the longitudinally-extending cylindrical section 202 meets the transversely-extending slab tip 208, which straight corner junction 210′ may mate with a the straight edge 278′ of the aperture 276. As further shown in each of FIGS. 9A-9C, the rounded edge 208a has a hemispheroidal shape. However, in alternative embodiments, the rounded slab tip 208a may also have the rounded cone shape depicted in FIGS. 8A-8B.

It may be appreciated that the plasma tuning rods of FIGS. 1-6B may have the tip configurations of any of the embodiments of FIGS. 7A-9C. For example, the plasma tuning portions 68, 68′, 70, 116, 116′, 132, 132′, 150, 150′ (or sections) of the plasma tuning rods 64, 66, which are configured to extend into a process chamber, may comprise a rod tip that is one of the non-cylindrical or slab tips 204a, 204b, or 208. Cylindrical section 202 may be referred to as a coupling section for coupling the plasma-tuning rod through the aperature 76 in a metal isolation wall of the process chamber, which may be part of the isolation assembly as described above. A shaped junction 210, 210′, for example a curved radius or a straight corner shape, is formed between the coupling section and the plasma tuning section. With reference to FIGS. 3A-6B, the outermost diameter of the outer dielectric portion, or shell, 104, 114, 124, 124′ 134, 134′, 158, 158′ in the plasma tuning section at or adjacent the junction 210, 210′ is greater than the diameter (D_{I}) of the aperature. In one embodiment, the shaped junction 210, 210′ has a mating shape to edge 278, 278′ between the aperture 76 and inner surface 280 of the metal isolation wall. Thus, the outer diameter of the dielectric shell may vary along the length, for example having a diameter in one section configured to provide the isolated coupling through the chamber wall and larger diameter in another section just inside the chamber wall to provide a seal or plug-type configuration where the dielectric of the rod interfaces with the metal of the isolation wall.

While the present invention has been illustrated by description of various embodiments and while those embodiments have been described in considerable detail, those skilled in the art will readily appreciate that many modifications are possible in the exemplary embodiment without materially departing from the novel teachings and advantages of this invention. The invention in its broader aspects is therefore not limited to the specific details and illustrative examples shown and described. Accordingly, departures may be made from such details without departing from the scope of the present invention.

What is claimed is:

1. A plasma-tuning rod for use in a microwave processing system comprising:
a first dielectric portion having a first outer diameter; and
a second dielectric portion surrounding the first dielectric portion and having a second outer diameter that is greater than the first outer diameter.

2. The plasma-tuning rod of claim 1, wherein the first dielectric portion includes a first material having a first dielectric constant and the second dielectric portion includes a second material having a second dielectric constant, wherein the first dielectric constant is equal to or greater than the second dielectric constant.

3. The plasma-tuning rod of claim 2, further comprising:
a strut disposed within the first dielectric portion and including a third material having a third dielectric constant, the third dielectric constant being different from the first dielectric constant.

4. The plasma-tuning rod of claim 3, wherein the third dielectric constant is the same as the second dielectric constant.

5. The plasma-tuning rod of claim 2, wherein the first dielectric portion comprises a plurality of layers, including at least one layer of the first material and at least one layer of a different material having a dielectric constant that is different from the first dielectric constant.

6. The plasma-tuning rod of claim 5, wherein the different material of the at least one layer is the second material of the second dielectric portion.

7. The plasma-tuning rod of claim 1, wherein the second dielectric portion comprises a plurality of layers, including at least one of the second material and at least one layer of a different material having a dielectric constant that is different from the second dielectric constant.

8. The plasma-tuning rod of claim 7, wherein the different material of the at least one layer is the first material of the first dielectric portion.

9. The plasma-tuning rod of claim 1, further comprising:
a band of gas disposed between the first dielectric portion and the second dielectric portion.

10. The plasma-tuning rod of claim 1, wherein the first material is aluminum oxide and the second material is silicon oxide.

11. The plasma-tuning rod of claim 1, further comprising:
a plasma tuning section for extending into a process chamber, the plasma tuning section comprising a rod tip;
a coupling section for coupling the plasma-tuning rod through an aperature in a metal isolation wall of the process chamber; and
a shaped junction between the plasma tuning section and the coupling section,
wherein the second outer diameter of the second dielectric portion in the plasma tuning section at or adjacent the shaped junction is greater than a diameter of the aperature.

12. The plasma-tuning rod of claim 11, wherein the shaped junction has a mating shape to an edge between the aperture and inner surface of the metal isolation wall.

13. The plasma-tuning rod of claim 11, wherein the rod tip has a hemispheroidal or rounded cone shape.

14. The plasma-tuning rod of claim 11, wherein the rod tip has a slab shape with a rounded edge.

15. A plasma-tuning rod comprising:
a first dielectric portion comprising one or more layers of materials; and
a second dielectric portion coaxial with respect to the first dielectric portion and comprising one or more layers of materials,
wherein at least one of the one or more layers of the first dielectric portion has a dielectric constant that is different than a dielectric constant of at least one of the one or more layers of the second dielectric portion.

16. The plasma-tuning rod of claim 15, further comprising:
a band of gas coaxially disposed between the first and second dielectric portions.

17. A microwave processing system comprising:
a process chamber configured to contain a plasma;
a substrate support within the process chamber and configured to support a substrate thereon;
a process gas supply system configured to deliver one or more process gases to the process chamber;
a microwave generator coupled to the process chamber and configured to generate an electromagnetic energy; and
a plurality of plasma-tuning rods operably coupled to the process chamber and configured to receive electromagnetic energy and transmit the electromagnetic energy into the process chamber for igniting at least one of the one or more process gases into the plasma,
wherein each plasma-tuning rod of the plurality comprises a core of a first dielectric material and a shell of a second dielectric material surrounding the core.

18. The microwave processing system of claim 17, wherein each plasma-tuning rod of the plurality includes a band of gas disposed between the core and the shell.

19. The microwave processing system of claim 17, wherein the first dielectric material has a first dielectric constant and the second dielectric material has a second dielectric constant, wherein the first dielectric constant is equal to or greater than the second dielectric constant.

20. The microwave processing system of claim 19, wherein the core of each of the plurality of plasma-tuning rods includes a strut disposed therein and including a third dielectric material having a third dielectric constant, the third dielectric constant being different than the first dielectric constant.

21. The microwave processing system of claim 20, wherein the third dielectric material is the same as the second dielectric material.

22. The microwave processing system of claim 17, wherein the core comprises a plurality of layers, including at least one layer of the first dielectric material and at least one layer of a different material having a dielectric constant that is different from the first dielectric constant.

23. The microwave processing system of claim 17, wherein the shell comprises a plurality of layers, including at least one of the second dielectric material and at least one layer of a different material having a dielectric constant that is different from the second dielectric constant.

24. The microwave processing system of claim 17, wherein the first material is aluminum oxide and the second material is silicon oxide.

25. The microwave processing system of claim 17, further comprising:
a first tuning system operably coupled to the process chamber and configured to transfer electromagnetic energy from the microwave generator to a first portion of the plurality of plasma-tuning rods.

26. The microwave processing system of claim 25, wherein each of the plasma-tuning rods includes a plasma tuning portion and an electromagnetic tuning portion, the plasma tuning portion extending from the first tuning system and into the process chamber and the electromagnetic tuning portion extending into the first tuning system.

27. The microwave processing system of claim 26, further comprising:
a plurality of tuning slabs corresponding to the electromagnetic tuning portion of a respective one of the plurality of plasma-tuning rods and forming an electromagnetic coupling region therewith, the plurality of tuning slabs configured to alter the electromagnetic field in the electromagnetic region.

28. The microwave processing system of claim 25, further comprising:
a second tuning system operably coupled to the process chamber and configured to transfer electromagnetic energy from the microwave generator to a second portion of the plurality of plasma-tuning rods.

29. The microwave processing system of claim 28, wherein each plasma-tuning rod of the first portion of the plurality extends from the first tuning system into the process chamber from a first side and each plasma-tuning rod of the second portion of the plurality extends into the process chamber from the second tuning system into the process chamber from a second side that opposes the first side.

30. The microwave processing system of claim 24, wherein the first and second portions of the plurality of plasma-tuning rods are arranged such that adjacent ones of the plurality of plasma-tuning rods alternate between the first portion on the first side of the process chamber and the second portion on the second side of the process chamber.

31. A microwave processing system comprising:
a process chamber configured to support a substrate and to contain a plasma therein;
a process gas supply system configured to deliver one or more process gases to the process chamber;
a microwave generator coupled to the process chamber and configured to generate an electromagnetic energy; and
at least one plasma-tuning rod operably coupled to the process chamber through an aperature in a metal isolation wall of the process chamber and configured to receive electromagnetic energy and transmit the electromagnetic energy into the process chamber for igniting at least one of the one or more process gases into the plasma,
wherein the at least one plasma-tuning rod comprises a plasma tuning section having a rod tip residing in the process chamber and a coupling section in the aperature of the metal isolation wall, with a junction therebetween, the outer diameter of the plasma tuning section being greater at or adjacent the junction than a diameter of the aperature.
